(19) United States
(12) Patent Application Publication
(10) Pub. No.: US 2026/0081590 A1
(43) Pub. Date: Mar. 19, 2026

(54) PARASITIC CAPACITANCE CANCELLATION CIRCUIT AND PARASITIC CAPACITANCE CANCELLATION METHOD

(71) Applicant: REALTEK SEMICONDUCTOR CORPORATION, Hsinchu (TW)

(72) Inventors: KAI-WEI YANG, Hsinchu (TW); Yen-Wei Liu, Hsinchu (TW); Chung-Chih Hung, Hsinchu City (TW)

(21) Appl. No.: 19/089,744

(22) Filed: Mar. 25, 2025

(30) Foreign Application Priority Data
Sep. 13, 2024 (TW) 113134942

(51) Int. Cl. H03K 17/16

(52) U.S. Cl. CPC H03K 17/16

(57) ABSTRACT

A parasitic capacitance cancellation circuit includes a first transistor, a first coupler, a second coupler, and a negative impedance generator. The first transistor includes a first terminal, a control terminal, and a second terminal. The first coupler is configured to couple the control terminal of the first transistor and the first terminal of the first transistor. The second coupler is configured to couple the control terminal of the first transistor and the second terminal of the first transistor. The negative impedance generator is configured to generate and provide a negative impedance to the control terminal of the first transistor to cancel a parasitic capacitance of the first transistor.

### BACKGROUND OF THE INVENTION

### 1. Field of the Invention

The present disclosure relates to a parasitic capacitance cancellation circuit and a parasitic capacitance cancellation method, especially to a parasitic capacitance cancellation circuit and a parasitic capacitance cancellation method that cancel parasitic capacitances of transistors.

### 2. Description of Related Art

With the advancement of technology, metal oxide semiconductor field effect transistors (MOSFETs) have emerged and are widely used in various circuits. However, MOSFETs have parasitic capacitances, and the capacitance values of the parasitic capacitances vary with different bias voltages (e.g., gate-source voltage Vgs). The foregoing parasitic capacitances can affect the performance of circuits.

### SUMMARY OF THE INVENTION

In some aspects, an object of the present disclosure is to, but not limited to, provides a parasitic capacitance cancellation circuit and a parasitic capacitance cancellation method that makes an improvement to the prior art.

An embodiment of a parasitic capacitance cancellation circuit of the present disclosure includes a first transistor, a first coupler, a second coupler, and a negative impedance generator. The first transistor includes a first terminal, a control terminal, and a second terminal. The first coupler is configured to couple the control terminal of the first transistor and the first terminal of the first transistor. The second coupler is configured to couple the control terminal of the first transistor and the second terminal of the first transistor. The negative impedance generator is configured to generate and provide a negative impedance to the control terminal of the first transistor to cancel a parasitic capacitance of the first transistor.

An embodiment of a parasitic capacitance cancellation method of the present disclosure includes: coupling a control terminal of a first transistor and a first terminal of the first transistor by a first coupler; coupling the control terminal of the first transistor and a second terminal of the first transistor by a second coupler; and generating and providing a negative impedance to the control terminal of the first transistor to cancel a parasitic capacitance of the first transistor by a negative impedance generator.

Technical features of some embodiments of the present disclosure make an improvement to the prior art. The parasitic capacitance cancellation circuit and the parasitic capacitance cancellation method of the present disclosure can be utilized to cancel parasitic capacitances of transistors.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

FIG. 1 shows an embodiment of a parasitic capacitance cancellation circuit of the present disclosure.

FIG. 2 shows an embodiment of a flow diagram of a parasitic capacitance cancellation method of the present disclosure.

FIG. 3 shows an embodiment of a related electrical characteristic curve of a parasitic capacitance cancellation circuit of the present disclosure.

FIG. 4 shows an embodiment of a parasitic capacitance cancellation circuit of the present disclosure.

FIG. 5 shows an embodiment of a parasitic capacitance cancellation circuit of the present disclosure.

FIG. 6 shows an embodiment of a related electrical characteristic curve of a parasitic capacitance cancellation circuit of the present disclosure.

### DETAILED DESCRIPTION OF THE PREFERRED EMBODIMENTS

To address the issue in prior art that the parasitic capacitance of the metal oxide semiconductor field effect transistor (MOSFET) affects the performance of the circuit, the present disclosure provides a parasitic capacitance cancellation circuit and a parasitic capacitance cancellation method, which will be explained in detail as shown below.

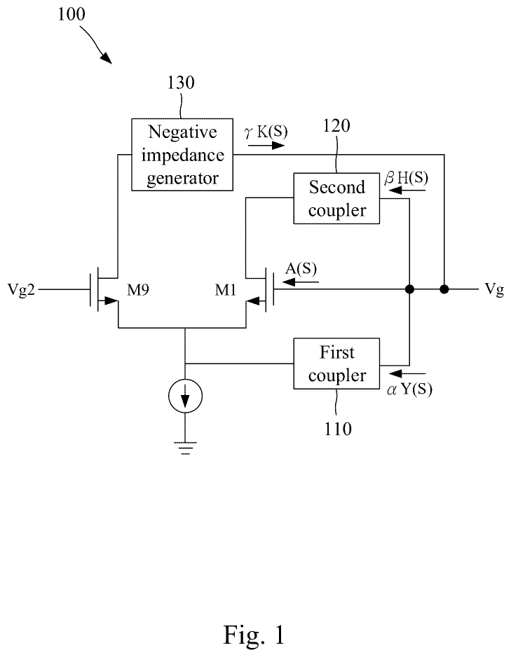

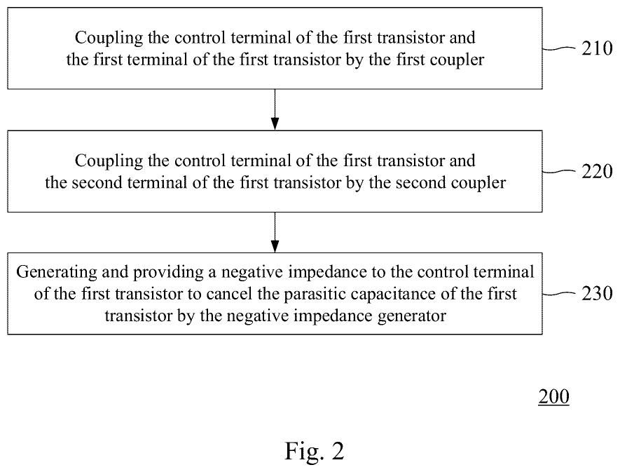

FIG. 1 shows an embodiment of a parasitic capacitance cancellation circuit 100 of the present disclosure. As shown in the figure, the parasitic capacitance cancellation circuit 100 includes a first transistor M1, a first coupler 110, a second coupler 120, and a negative impedance generator 130. The first transistor M1 includes a first terminal (e.g., a source), a control terminal (e.g., a gate), and a second terminal (e.g., a drain). For facilitating the understanding of the operations of the parasitic capacitance cancellation circuit 100 of the present disclosure, reference is now made to FIG. 2. FIG. 2 shows an embodiment of a flow diagram of a parasitic capacitance cancellation method 200 of the present disclosure.

Referring to FIG. 1 and FIG. 2, in step 210, coupling the control terminal of the first transistor M1 and the first terminal of the first transistor M1 by the first coupler 110. In step 220, coupling the control terminal of the first transistor M1 and the second terminal of the first transistor M1 by the second coupler 120. In step 230, generating and providing a negative impedance to the control terminal of the first transistor M1 to cancel the parasitic capacitance of the first transistor M1 by the negative impedance generator 130.

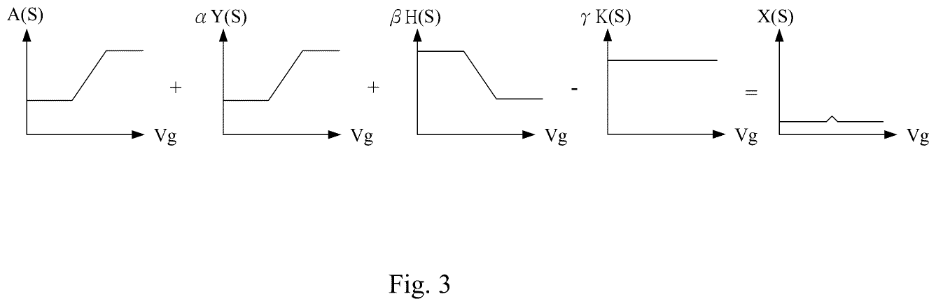

Referring to FIG. 1 and FIG. 3, the initial parasitic capacitance of the first transistor M1 is A(S). The present disclosure can utilize the first coupler 110 to provide a first parameter αY(S), and the present disclosure can utilize the second coupler 120 to provide a second parameter βH(S), thereby adjusting the initial parasitic capacitance A(S) of the first transistor M1 to be less affected by bias voltage (e.g., gate-source voltage Vgs). In some embodiments, the parameters α and β of the present disclosure can be set based on actual requirements to adjust the ratio of Y(S) and H(S), thereby further tuning the initial parasitic capacitance A(S) of the first transistor M1 to be less affected by bias voltage (e.g., gate-source voltage Vgs).

In addition, the present disclosure further utilizes the negative impedance generator 130 to provide a third parameter γK(S) to form a negative impedance, thereby canceling the initial parasitic capacitance A(S) of the first transistor M1. As shown in FIG. 3, the equivalent parasitic capacitance X(S) of the first transistor M1 is smaller than the initial parasitic capacitance A(S), and the equivalent parasitic capacitance X(S) is almost unaffected by variations in bias voltage. In some embodiments, the parameters α, β, and γ in the present disclosure can be set based on actual requirements to cancel the initial parasitic capacitance A(S) of the first transistor M1 and ensure that the equivalent parasitic capacitance X(S) remains nearly unaffected by variations in bias voltage. It is noted that although the embodiments of the present disclosure illustrate only one set of α and Y(S), one set of β and H(S), and one set of γ and K(S), the present disclosure can be configured with multiple sets of α and Y(S), multiple sets of β and H(S), and multiple sets of γ and K(S) based on actual requirements to further enhance the efficiency of canceling the initial parasitic capacitance A(S) of the first transistor M1 and ensure that the equivalent parasitic capacitance X(S) remains nearly unaffected by variations in bias voltage.

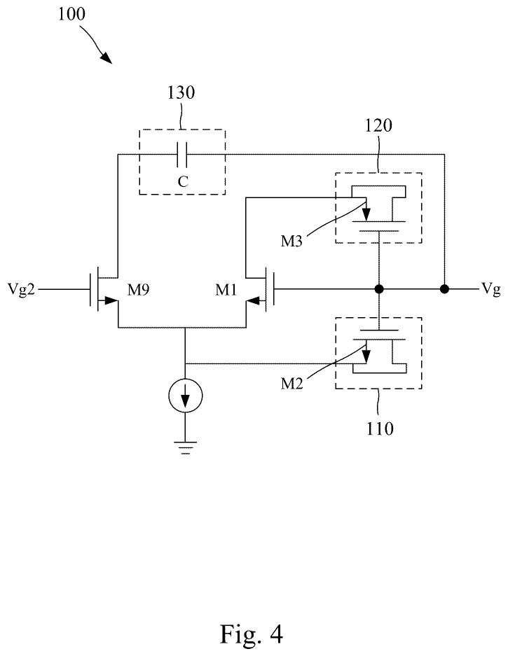

FIG. 4 shows an embodiment of a parasitic capacitance cancellation circuit 100 of the present disclosure. Compared with the parasitic capacitance cancellation circuit 100 in FIG. 1, FIG. 4 illustrates a detailed circuit diagram of the parasitic capacitance cancellation circuit 100. As shown in FIG. 4, the first coupler 110 includes a second transistor M2, and the second transistor M2 includes a first terminal, a control terminal, and a second terminal. The first terminal (e.g., the left terminal) of the second transistor M2 is coupled to the first terminal (e.g., lower terminal) of the first transistor M1. The control terminal (e.g., the gate terminal) of the second transistor M2 is coupled to the control terminal (e.g., the gate terminal) of the first transistor M1. The second terminal (e.g., the right terminal) of the second transistor M2 is coupled to the first terminal (e.g., the left terminal) of the second transistor M2 and the first terminal (e.g., the lower terminal) of the first transistor M1.

In some embodiments, the second coupler 120 includes a third transistor M3, and the third transistor M3 includes a first terminal, a control terminal, and a second terminal. The first terminal (e.g., the left terminal) of the third transistor M3 is coupled to the second terminal (e.g., the upper terminal) of the first transistor M1. The control terminal (e.g., the gate terminal) of the third transistor M3 is coupled to the control terminal (e.g., the gate terminal) of the first transistor M1 and the control terminal (e.g., the gate terminal) of the second transistor M2. The second terminal (e.g., the right terminal) of the third transistor M3 is coupled to the first terminal (e.g., the left terminal) of the third transistor M3 and the second terminal (e.g., the upper terminal) of the first transistor M1. In some embodiments, the first transistor M1, the second transistor M2, the third transistor M3, and the transistor M9 can be metal oxide semiconductor field effect transistors (MOSFETs). However, the present disclosure is not limited to the aforementioned embodiment, which serves merely as an illustrative example of one implementation of the present disclosure. In other embodiments, the first transistor M1, the second transistor M2, the third transistor M3, and the transistor M9 may also be other suitable components depending on actual requirements.

In some embodiments, the negative impedance generator 130 includes a capacitor C, and the capacitor C includes a first terminal and a second terminal. The first terminal (e.g., the left terminal) of the capacitor C is configured to receive a first control signal (e.g., the control signal provided by the transistor M9 according to the signal Vg2, and the voltages of the signals Vg2 and Vg are different), and the second terminal (e.g., the right terminal) of the capacitor C is coupled to the control terminal (e.g., the gate terminal) of the first transistor M1. The control terminal (e.g., the gate terminal) of the first transistor M1 is configured to receive the second control signal Vg. The negative impedance generator 130 provides the negative impedance to the control terminal (e.g., the gate terminal) of the first transistor M1 according to the first control signal (e.g., the control signal provided by the transistor M9 according to the signal Vg2, and the voltages of the signals Vg2 and Vg are different). However, the present disclosure is not limited to the aforementioned embodiment, which serves merely as an illustrative example of one implementation of the present disclosure. In other embodiments, the negative impedance generator 130 may also be other suitable components depending on actual requirements.

Referring to FIG. 3, the parasitic capacitance A(S) of the first transistor M1 includes a parasitic capacitance A(S) and control signal Vg curve. The second transistor M2 is configured to provide the first parameter αY(S) and control signal Vg curve, the third transistor M3 is configured to provide the second parameter βH(S) and control signal Vg curve, and the capacitor C of the negative impedance generator 130 provides the third parameter γK(S) and control signal Vg curve. The foregoing first parameter αY(S) and control signal Vg curve, the second parameter βH(S) and control signal Vg curve, and the third parameter γK(S) and control signal Vg curve are configured to cancel the parasitic capacitance A(S) and control signal Vg curve. As a result, the equivalent parasitic capacitance X(S) of the first transistor M1 is smaller than the initial parasitic capacitance A(S), and the equivalent parasitic capacitance X(S) is almost unaffected by variations in bias voltage.

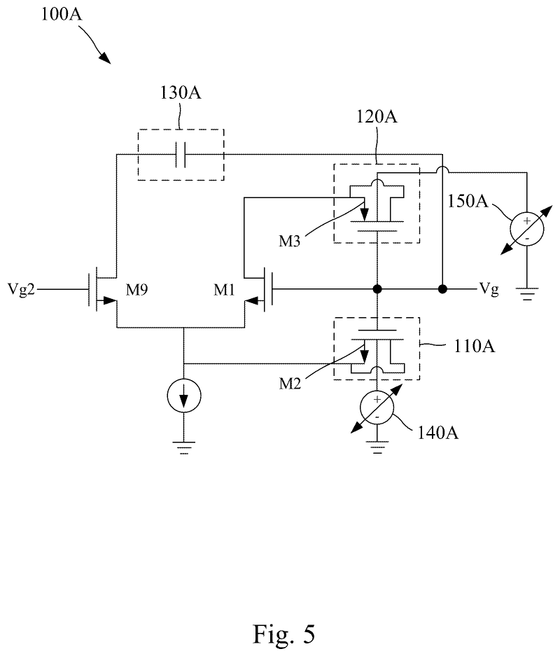

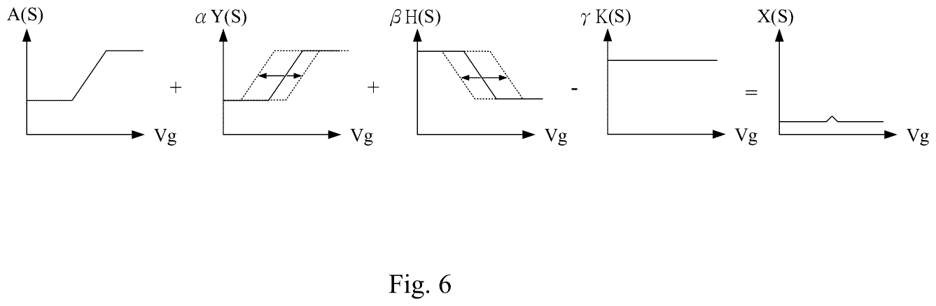

FIG. 5 shows an embodiment of a parasitic capacitance cancellation circuit 100 of the present disclosure. Compared with the parasitic capacitance cancellation circuit 100 in FIG. 4, the parasitic capacitance cancellation circuit 100A in FIG. 5 further includes a first power supply 140A and a second power supply 150A. As shown in FIG. 5, the first power supply 140A is configured to provide a first power to the body terminal of the second transistor M2. The second power supply 150A is configured to provide a second power to the body terminal of the third transistor M3. To understand the effects of the first power supply 140A and the second power supply 150A, reference is made to FIG. 6 as shown below.

FIG. 6 shows an embodiment of a related electrical characteristic curve of a parasitic capacitance cancellation circuit 100A of the present disclosure. The initial parasitic capacitance of the first transistor M1 is A(S). The present disclosure can utilize the first coupler 110A to provide a first parameter αY(S), and the present disclosure can utilize the first power supply 140A to provide a first power to the body terminal of the second transistor M2 to adjust the first parameter αY(S) and control signal Vg curve. When the first power increases, the body voltage of the second transistor M2 rises, the first parameter αY(S) and control signal Vg curve is therefore shifted to the left. When the first power decreases, the body voltage of the second transistor M2 drops, the first parameter αY(S) and control signal Vg curve is therefore shifted to the right.

In addition, the present disclosure can utilize the second coupler 120A to provide a second parameter βH(S), and the present disclosure can utilize the second power supply 150A to provide a second power to the body terminal of the third transistor M3 to adjust the second parameter βH(S) and control signal Vg curve. When the second power increases, the body voltage of the third transistor M3 rises, the second parameter βH(S) and control signal Vg curve is therefore shifted to the left. When the second power decreases, the body voltage of the third transistor M3 drops, the second parameter βH(S) and control signal Vg curve is therefore shifted to the right.

Therefore, the present disclosure can utilize the first power supply 140A and the second power supply 150A to adjust the first parameter αY(S) and control signal Vg curve and the second parameter βH(S) and control signal Vg curve in order to regulate the parasitic capacitance A(S) and control signal Vg curve, such the foregoing adjustment ensures the initial parasitic capacitance A(S) of the first transistor M1 to remain almost unaffected by variations in bias voltage (e.g., gate-source voltage Vgs). In addition, the present disclosure further utilizes the negative impedance generator 130A to provide a third parameter γK(S) for forming a negative impedance to cancel the initial parasitic capacitance A(S) of the first transistor M1. As shown in FIG. 6, the equivalent parasitic capacitance X(S) of the first transistor M1 is smaller than the initial parasitic capacitance A(S), and the equivalent parasitic capacitance X(S) is almost unaffected by variations in bias voltage.

It is noted that the present disclosure is not limited to the embodiments as shown in FIG. 1 to FIG. 6, they are merely examples for illustrating the implements of the present disclosure, and the scope of the present disclosure shall be defined on the basis of the claims as shown below. In view of the foregoing, it is intended that the present disclosure covers modifications and variations to the embodiments of the present disclosure, and modifications and variations to the embodiments of the present disclosure also fall within the scope of the following claims and their equivalents.

As described above, technical features of some embodiments of the present disclosure make an improvement to the prior art. The parasitic capacitance cancellation circuit and the parasitic capacitance cancellation method of the present disclosure can be utilized to cancel parasitic capacitances of transistors, and the parasitic capacitance remains almost unaffected by variations in bias voltage.

It is noted that people having ordinary skill in the art can selectively use some or all of the features of any embodiment in this specification or selectively use some or all of the features of multiple embodiments in this specification to implement the present invention as long as such implementation is practicable; in other words, the way to implement the present invention can be flexible based on the present disclosure.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A parasitic capacitance cancellation circuit, comprising:
a first transistor, comprising a first terminal, a control terminal, and a second terminal;
a first coupler, configured to couple the control terminal of the first transistor and the first terminal of the first transistor;
a second coupler, configured to couple the control terminal of the first transistor and the second terminal of the first transistor; and
a negative impedance generator, configured to generate and provide a negative impedance to the control terminal of the first transistor to cancel a parasitic capacitance of the first transistor.

2. The parasitic capacitance cancellation circuit of claim 1, wherein the first coupler comprises a second transistor, and the second transistor comprises:
a first terminal, coupled to the first terminal of the first transistor;
a control terminal, coupled to the control terminal of the first transistor; and
a second terminal, coupled to the first terminal of the second transistor and the first terminal of the first transistor.

3. The parasitic capacitance cancellation circuit of claim 2, wherein the second coupler comprises a third transistor, and the third transistor comprises:
a first terminal, coupled to the second terminal of the first transistor;
a control terminal, coupled to the control terminal of the first transistor and the control terminal of the second transistor; and
a second terminal, coupled to the first terminal of the third transistor and the second terminal of the first transistor.

4. The parasitic capacitance cancellation circuit of claim 3, wherein the parasitic capacitance of the first transistor comprises a parasitic capacitance and control signal curve, the second transistor is configured to provide a first parameter and control signal curve, and the third transistor is configured to provide a second parameter and control signal curve, wherein the first parameter and control signal curve and the second parameter and control signal curve are configured to regulate the parasitic capacitance and control signal curve.

5. The parasitic capacitance cancellation circuit of claim 4, further comprising:
a first power supply, configured to provide a first power to a body terminal of the second transistor.

6. The parasitic capacitance cancellation circuit of claim 5, further comprising:
a second power supply, configured to provide a second power to a body terminal of the third transistor.

7. The parasitic capacitance cancellation circuit of claim 6, wherein the first power supply adjusts the first parameter and control signal curve through adjusting the first power, and the second power supply adjusts the second parameter and control signal curve through adjusting the second power.

8. The parasitic capacitance cancellation circuit of claim 7, wherein the first parameter and control signal curve after adjustment and the second parameter and control signal curve after adjustment are configured to regulate the parasitic capacitance and control signal curve.

9. The parasitic capacitance cancellation circuit of claim 1, wherein the negative impedance generator comprises a capacitor, and the capacitor comprises:
a first terminal, configured to receive a first control signal; and
a second terminal, coupled to the control terminal of the first transistor;
wherein the control terminal of the first transistor is configured to receive a second control signal, wherein the negative impedance generator provides the negative impedance to the control terminal of the first transistor according to the first control signal.

10. A parasitic capacitance cancellation method, comprising:
coupling a control terminal of a first transistor and a first terminal of the first transistor by a first coupler;
coupling the control terminal of the first transistor and a second terminal of the first transistor by a second coupler; and
generating and providing a negative impedance to the control terminal of the first transistor to cancel a parasitic capacitance of the first transistor by a negative impedance generator.
